(19) United States
(12) Patent Application Publication
(10) Pub. No.: US 2008/0169856 A1
(43) Pub. Date: Jul. 17, 2008

(54) SYSTEM AND APPARATUS TO ACTIVATE ELECTRIC TRIGGERS

(76) Inventors: Francisco Jose Roman C., Bogota (CO); Jose Felix Vega S., Colombia (CO)

Correspondence Address: JOHN J. MARTINEZ MD. JD., 10 PALMER AVENUE, CROTON ON HUDSON, NY, 10520, US

(21) Appl. No.: 11/833,424

(22) Filed: Aug. 3, 2007

(30) Foreign Application Priority Data
Jan. 8, 2007 (CO) 07-078673

(51) Int. Cl. H03K 3/00

(52) U.S. Cl. 327/181

(57) ABSTRACT

The present invention provides a current impulse generator that is fed by a high voltage source. The high voltage from the source creates an electric field which turns into a corona current by means of a corona current source. The corona current source charges a floating electrode with electrostatic energy which is rapidly discharged by means of a discharge switch into a spherical electrode producing a current impulse. The spherical electrode transmits the current impulse to an antenna which emits an electromagnetic wideband energy beam which actuates on electric triggers from a distance.

### CROSS REFERENCE TO RELATED PATENTS OR APPLICATIONS

This application is related to the U.S. Pat. No. 5,892,363 issued Apr. 6, 1999 to Francisco Roman; U.S. Pat. No. 5,923,130 issued Jul. 13, 1999 to Francisco Roman; U.S. Pat. No. 5,939,841 issued Aug. 17, 1999 to Francisco Roman; and Colombian Patent No. 28417 issued Jan. 31, 2001 to Francisco Roman. The inventor for these three U.S. patents and this Colombian patent is one of the same inventors of this application. Said three U.S. patents and said Colombian patent are hereby incorporated herein in their entirety by reference.

### BACKGROUND OF THE INVENTION

1. Field of the Invention

The present invention relates to the use of a floating electrode apparatus wherein said apparatus emits, throughout an antenna, current impulses projected as wideband electromagnetic beams, wherein said beams actuate over explosive devices with electric triggers.

2. Description of Related Art

Devices or apparatuses that emit electromagnetic fields to deactivate electric triggered mines (electrical explosive devices (EED)) have been described. However, mine deactivating devices described in the literature are not portable requiring special equipment to mobilize said devices. In addition, mine deactivating devices described in the literature emit only electromagnetic fields of one specific wave length, characteristic that becomes a limitation since there is the need calibrate or match the emitted specific wave length electromagnetic field with the electromagnetic signature of the mine trigger.

One example, which shows the need to match the emitted impulses with the electromagnetic signature of mine triggers, is the device described by Willis L. Lee in U.S. Pat. No. 3,707,913 (Jan. 2, 1973). Willis describes an apparatus for destroying electro explosive devices that requires a matching network.

It would be advantageous to provide a truly portable mine deactivating device which does not require a matching network or calibration to match mine triggers' electromagnetic signature.

### SUMMARY OF THE INVENTION

The present invention provides a current impulse generator or an apparatus to deactivate electrical explosive devices (EED), wherein the current impulse generator generates current impulses that turn into an electromagnetic wideband energy beam, wherein said electromagnetic wideband energy beam contains many overlapping electromagnetic fields of different wave lengths, and wherein said electromagnetic wideband energy beam actuates over an electrically triggered explosive device, from a distance, by injecting an electrical current over the cables and trigger circuits of said explosive device.

Because of the many different electromagnetic wave lengths of the wideband energy beam, the current impulse generator of the present invention does not require a matching network or calibrating to match a mine trigger electromagnetic signature, wherein the term “electromagnetic signature” refers to the specific wave length of the electromagnetic field that activates the mine trigger.

In addition, the current impulse generator of the present invention can be adapted to be the size of a bazooka, overcoming portability limitations.

In a preferred embodiment, the present invention comprises:
A. An electrically floating electrode coaxially insulated and placed in the interior of a first enclosure conformed by a metallic container and an insulating ring, wherein the metallic container has a first end and a second end, wherein the insulating ring is at the first end of the metallic container, wherein the metallic container is grounded throughout a conductor, and wherein the isolating ring continues with a second enclosure which is connected to a high voltage source that creates a high electric field inside the second enclosure;
B. A corona current source located between the first enclosure and the second enclosure, wherein the corona current source is connected to the floating electrode;
C. A discharged switch located inside the metallic container toward the second end of said metallic container, wherein said discharged switch is conformed by one end of the floating electrode, an spherical electrode; and a gap between the spherical electrode and the floating electrode;
D. An antenna external to the metallic container;
E. A transmission line which connects the spherical electrode to the antenna;

Wherein the high electric field created by the high voltage source is converted to a corona current by the corona current source, wherein said corona current source charges the floating electrode with electrostatic energy, wherein said electrostatic energy is discharged throughout the discharge switch with a high repeatability rate generating a plurality of current impulses, wherein each of one of the current impulses has a highly enhanced amperage with respect to the amperage of the high voltage source current, wherein the plurality of current impulses is transmitted from the spherical electrode to the antenna, and wherein the plurality of generated current impulses transmitted to the antenna turns into an electromagnetic wideband energy beam of many overlapping wave lengths.

In one embodiment of the present invention, the current impulse generator has a transmission line that terminates in a short circuit or corona source that connects to the antenna, such that there is fixed matching impedance.

In other aspect of the present invention the current impulse generator further comprises an insulator between the spherical electrode and the internal surface of the metallic container. Said insulator may be replaced by an electrical device such as a resistor to transform the current impulses into voltage impulses.

In another aspect of the present invention, the metallic container of the current impulse generator is a metallic cylinder.

In a further aspect of the present invention, the current impulse generator also comprises an external oscilloscope to measure current signals from the generator, wherein the external oscilloscope connects throughout a cable to a Rogowski coil that is inside the metallic container.

In an additional aspect of the present invention, the floating electrode of the current impulse generator has one rounded shaped end, and wherein said rounded shaped end is directly oriented toward the gap of the discharge switch in such a way that the rounded shaped end becomes a part of the discharged switch.

In one more aspect of the present invention, the gap of the discharge switch of the current impulse generator is filled with a gas or liquid.

The present invention also provides a method to deactivate explosive devices comprising:
a. Providing a high electric field to an enclosure;
b. Turning said high electric field into a corona current by means of a corona current source;
c. Using the corona current source to charge a floating electrode with electrostatic energy;
d. Generating current impulses by highly repeated discharge of the electrostatic energy from the floating electrode by means of a discharge switch, wherein said discharge switch has a gap and a spherical electrode;
e. Transmitting the generated current impulses from the spherical electrode to an antenna by means a transmission line, wherein the antenna generates a wideband electromagnetic energy beam;

Wherein the amperage of the generated current impulse (in the order of hundreds of amps or kiloamps) has been highly enhanced with respect to the amperage of the high voltage electrical current (in the order of milliamps) that generated the high electric field.

Objectives and additional advantages of the present invention will become more evident in the description of the figures, the detailed description of the invention and the claims.

### BRIEF DESCRIPTION OF THE DRAWINGS

FIG. 1 shows one of the embodiments of the current impulse generator of the present invention. In this embodiment the current impulse generator has an ultra wide band (UWB) antenna connected to the transmission line.

FIG. 2 shows another embodiment of the current impulse generator of the present invention. In this embodiment an antenna is incorporated to the current impulse generator.

FIG. 3 shows an embodiment of the current impulse generator of the present invention. In this embodiment the current impulse generator has an antenna which contains needles to initiate corona discharges in its surface.

FIG. 4B shows an embodiment of the current impulse generator of the present invention. In this embodiment the current impulse generator has an antenna connected to a transmission line that terminates in a short circuit or in matching impedance.

### DETAILED DESCRIPTION OF THE INVENTION

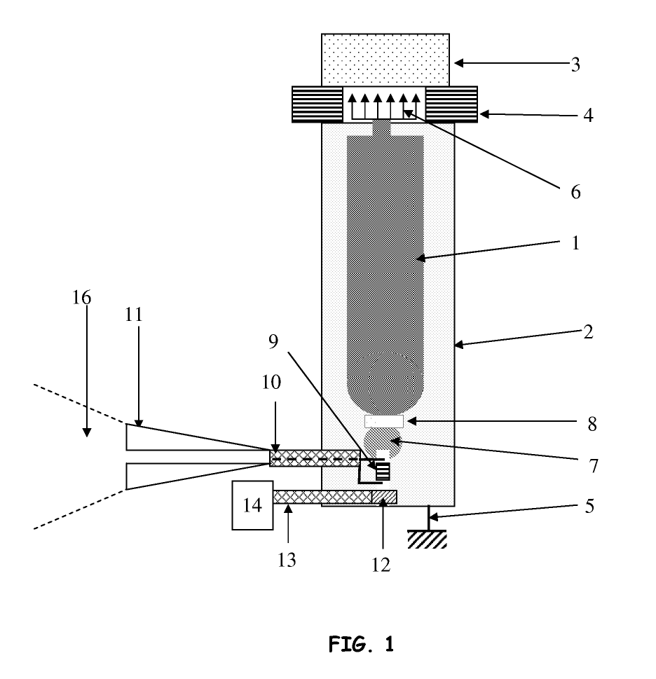

FIG. 1. shows the most preferred embodiment of the current impulse generator of the present invention. The current impulse generator comprises: A. An electrically floating electrode (1) coaxially isolated in the interior of a first enclosure conformed by a metallic container (2) and an insulating ring (4), wherein the metallic container (2) is grounded throughout a conductor (5), and wherein the isolating ring (4) continues with a second enclosure (3) which is connected to a high voltage source; B. A corona current source (6) located between the metallic container (2) and the second enclosure (3) at the level of the isolating ring (4), wherein the corona current source (6) is made of needles electrically connected to the floating electrode (1), wherein the corona current source (6) is connected to the floating electrode (1); C. A discharged switch (7 and 8) located inside the metallic container (2), wherein said discharged switch (7 and 8) has an spherical electrode (7) and a gap (8) between the spherical electrode (7) and the floating electrode (1); D. An antenna (11) external to the metallic container (2); and E. A transmission line (10) which connects the spherical electrode (7) to the antenna (11), wherein the antenna emits an electromagnetic wideband energy beam (16).

When high voltage is applied to the second enclosure (3) the electric field on the surface of the corona current charger (6) is amplified. As a result, a ionic current initiate at the tips of the needles of the corona current charger (6). Thus, the electric field from the high voltage source is converted to a corona current that charges the floating electrode (1) with electrostatic energy. Said electrostatic energy is discharged repeatedly throughout the discharge switch (7 and 8) generating current impulses which are transmitted from the spherical electrode (7) to the antenna (11), and wherein generated current impulses transmitted to the antenna (11) turn into an electromagnetic wideband energy beam (16). The current impulses amperage is several orders of magnitude larger than the amperage of the high voltage source.

In other embodiments of the present invention, the current impulse generator has the floating electrode (1) isolated from the metallic container (2) with solid, liquid or pressurized gas insulating materials.

For the purposes of the present invention, the terms “electromagnetic wideband energy beam” (16) is defined as the sum of many overlapping different wave length electromagnetic fields that have been emitted from the current impulse generator throughout the antenna (11), as the current impulse generator emits high derivative current impulses.

The current impulse generator of the present invention is an electrostatic current generator developed to produce current impulses with rise time of few nanoseconds (ns) and current amplitudes in the order of hundreds of Amperes (A) or kiloamperes (kA). The current impulse generator of the present invention has a corona current source or charger (6) that charges quickly the floating electrode (1) with electrostatic energy which is rapidly discharged and transmitted to the antenna (11). As a result, the current impulse generator of the present invention can generate repetitive high derivative current impulses that turn into repetitive impulses with a wideband frequency content. These repetitive current impulses turn into emitted wideband electromagnetic fields, forming an electromagnetic wideband energy beam (16).

In the preferred embodiment of the present invention, the antenna (11) of the current impulse generator is an ultra wide band (UWB) antenna (11). However, other type of antennas that can turn current impulses into electromagnetic fields can also be used.

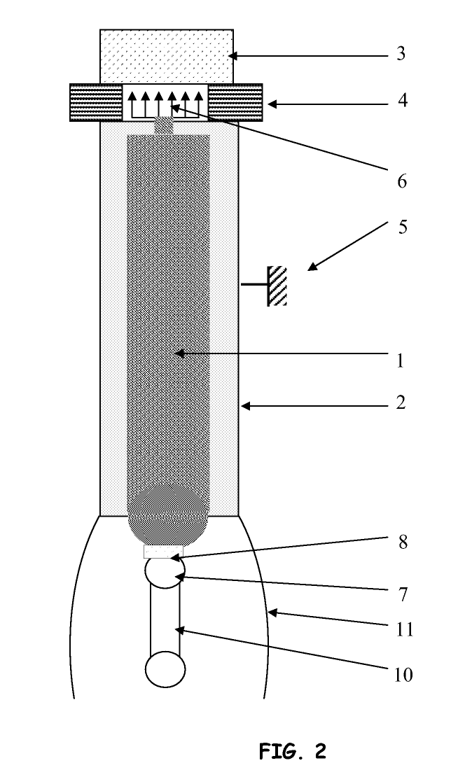

In another embodiment of the present invention, as it is shown in FIG. 2., the antenna (11) can be incorporated into the current impulse generator by coaxially connecting it to the metallic container (2).

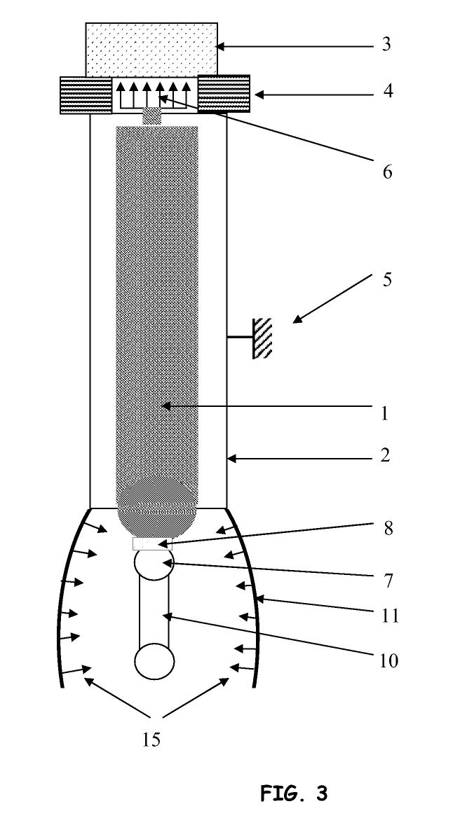

In one more embodiment of the present invention, as it is shown is FIG. 3., the antenna, which is connected to the metallic container (2), is covered with corona needles (15) to match the transmission line with the antenna.

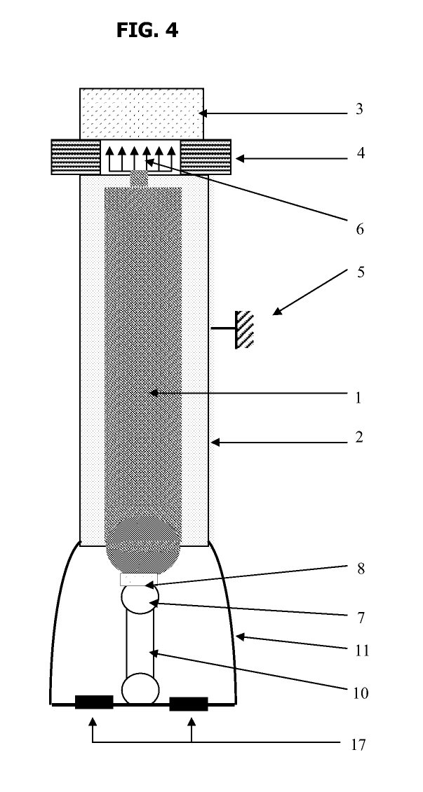

In another embodiment of the present invention, as it is shown in FIG. 4., the current impulse generator has an antenna (11) that is connected to a transmission line (10) which terminates in a short circuit (17) or corona source, such that there is fixed matching impedance.

In a further aspect of the present invention, the current impulse generator further comprises an insulator (9) between the spherical electrode (7) and the internal surface of the metallic container (2). Este insulator (9) avoids the electrical sparking from the spherical electrode (7) to the metallic container (2), to let the transmission of a current impulse to the antenna (11). Said insulator (9) can be replaced by a matching impedance to transmit a voltage impulse to the antenna.

In other embodiments of the present invention, the insulator (9) may be replaced by an electrical device such as a resistor to transform the current impulses into voltage impulses.

In a preferred aspect of the present invention, the metallic container (2) of the current impulse generator is a metallic cylinder (2).

In a further aspect of the present invention, the current impulse generator also comprises an external oscilloscope (14) to measure current signals from the generator, wherein the external oscilloscope (14) connects throughout a cable (13) to a Rogowski coil (12) that is inside the metallic container (2).

In a preferred aspect of the present invention, the electrically floating electrode (1) of the current impulse generator has cylindrical form, wherein the cylindrical electrically floating electrode has one end shaped as a semi-sphere, and wherein said semi-sphere shaped end is directly oriented toward the gap (8) of the discharge switch (7 and 8), in such a way, that the semi-sphere shaped end becomes another part of the discharged switch (7 and 8). The floating electrode may have other forms, e.g., conical, and spherical. Preferably, said floating electrode is round ended toward the discharged switch gap.

In one more aspect of the present invention, the gap (8) of the discharge switch (7 and 8) of the current impulse generator is filled and isolated with a compressed gas or a liquid.

In one additional aspect of the present invention, the floating electrode (1) may be isolated from the metallic container (2) with a compressed gas, or a solid or a liquid insulation.

The present invention also provides a method to deactivate mines comprising: a. Providing a high electrical field to an enclosure; b. Turning said high electrical field into a corona current by means of a corona current source (6); c. Using the corona current source (6) to charge a floating electrode (1) with electrostatic energy; d. Generating a current impulse by the discharge of the electrostatic energy from the floating electrode (1) by means of a discharge switch (7 and 8), wherein said discharge switch (7 and 8) has a gap (8) and a spherical electrode (7); e. Transmitting the generated current impulse from the spherical electrode (7) to an antenna (11) by means a transmission line (10); Wherein the amperage of the generated current impulse (in the order of several hundred amps, or in the order of kiloamps) has been highly enhanced with respect to the amperage of the high voltage electrical source (in the order of milliamps).

In one embodiment of the method of the present invention, the transmission line (10) can be matched to the antenna (11) by means of a matching resistor, or a short circuit, or corona discharges in needles.

While the description presents the preferred embodiments of the present invention, additional changes can be made in the form and disposition of the parts without distancing from the basic ideas and principles comprised in the following claims:

1. A current impulse generator for deactivation of explosive devices comprising:
A. A floating electrode coaxially placed in the interior of a first enclosure conformed by a metallic container and an insulating ring, wherein the metallic container has a first end and a second end, wherein the insulating ring is at the first end of the metallic container, and wherein the metallic container is grounded throughout a conductor, and wherein the isolating ring continues with a second enclosure which is connected to a high voltage source that creates a high electric field inside the second enclosure;
B. A corona current source located between the first enclosure and the second enclosure, wherein the corona current source is connected to the floating electrode;
C. A discharged switch located inside the metallic container toward the second end of said metallic container, wherein said discharged switch is conformed by one end of the floating electrode, an spherical electrode; and a gap between the spherical electrode and the floating electrode;
D. An antenna external to the metallic container;
E. A transmission line which connects the spherical electrode to the antenna;
Wherein the high electric field created by the high voltage source is converted to a corona current by the corona current source, wherein said corona current source charges the floating electrode with electrostatic energy, wherein said electrostatic energy is discharged throughout the discharge switch with a high repeatability rate generating a plurality of current impulses, wherein each of one of the current impulses has a highly enhanced amperage with respect to the amperage of the high voltage source, wherein the plurality of current impulses is transmitted from the spherical electrode to the antenna, and wherein the plurality of generated current impulses transmitted to the antenna turns into an electromagnetic wideband energy beam of many overlapping wave lengths, and wherein said electromagnetic wideband energy beam actuates over an electrically triggered explosive device, from a distance, by injecting an electrical current over the cables and trigger circuits of said explosive device.

2. The current impulse generator of claim 1, wherein the floating electrode is isolated from the metallic container with solid insulating materials.

3. The current impulse generator of claim 1, wherein the floating electrode is isolated from the metallic container with liquid insulating materials.

4. The current impulse generator of claim 1, wherein the floating electrode is isolated from the metallic container with pressurized gas insulating materials.

5. The current impulse generator of claim 1, wherein said generator has a transmission line that terminates in a short circuit that connects to the antenna, such that there is fixed matching impedance.

7. The current impulse generator of claim 1, wherein said generator has a transmission line that terminates in a corona source that connects to the antenna, such that there is fixed matching impedance.

7. The current impulse generator of claim 1, wherein said generator further comprises an insulator between the spherical electrode and the internal surface of the metallic container;

8. The current impulse generator of claim 7, wherein the insulator is replaced by a resistor, wherein the resistor transforms the current impulses into voltage impulses.

9. The current impulse generator of claim 1, wherein the metallic container is a metallic cylinder.

10. The current impulse generator of claim 1, wherein said generator comprises an external oscilloscope to measure current signals from the generator, wherein the external oscilloscope connects throughout a cable to a Rogowski coil that is inside the metallic container.

11. The current impulse generator of claim 1, wherein the floating electrode has one rounded shaped end, and wherein said rounded shaped end is directly oriented toward the gap of the discharge switch in such a way that the rounded shaped end becomes a part of the discharged switch.

12. The current impulse generator of claim 1, wherein the gap of the discharge switch is filled with a gas.

13. The current impulse generator of claim 1, wherein the gap of the discharge switch is filled with liquid.

14. A method to deactivate explosive devices comprising:
a. Providing an electric field to an enclosure;
b. Turning said electric field into a corona current by means of a corona current source;
c. Using the corona current source to charge a floating electrode with electrostatic energy;
d. Generating current impulses by highly repeated discharge of the electrostatic energy from the floating electrode by means of a discharge switch, wherein said discharge switch is conformed by one end of the floating electrode, a gap, and a spherical electrode;
e. Transmitting the generated current impulses from the spherical electrode to an antenna by means a transmission line, wherein the antenna generates a wideband electromagnetic energy beam;
Wherein generated current impulses transmitted to the antenna turn into an electromagnetic wideband energy beam, wherein said electromagnetic wideband energy beam contains many overlapping electromagnetic wave lengths, and wherein said electromagnetic wideband energy beam actuates over an electrically triggered explosive device, from a distance, by injecting an electrical current over the cables and trigger circuits of said explosive device.

15. The method of claim 14, wherein said method further comprises converting the current impulses into voltage impulses by matching the transmission line to the antenna by mean of a matching resistor.

16. The method of claim 14, wherein said method further comprises converting the current impulses into voltage impulses by matching the transmission line to the antenna by mean of a short circuit.

17. The method of claim 14, wherein said method further comprises converting the current impulses into voltage impulses by matching the transmission line to the antenna by mean of corona discharges in needles.
